(19) United States
(12) Patent Application Publication
(10) Pub. No.: US 2012/0223201 A1
(43) Pub. Date: Sep. 6, 2012

(54) MOUNTING ASSEMBLY FOR STORAGE DEVICE

(75) Inventors: YUN-LUNG CHEN, Tu-Cheng (TW); LIANG-CHIN WANG, Tu-Cheng (TW); JIAN HU, Wuhan City (CN); YU-MING XIAO, Wuhan City (CN); ZAN LI, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/288,975

(22) Filed: Nov. 4, 2011

(30) Foreign Application Priority Data
Mar. 1, 2011 (CN) 201110048404.4

(51) Int. Cl. H05K 7/00; F16M 13/00

(52) U.S. Cl. 248/309.1

(57) ABSTRACT

A mounting assembly includes an enclosure, a mounting device and a resilient member. The enclosure defines a mounting hole. The mounting device includes an engaging member, a drive member, and an engaging rod. A positioning groove and a clipping groove are defined in the engaging member. The drive member includes a limiting block. The resilient member is surrounding the engaging rod. The drive member is moveable relative to the engaging member between an unlocked position and a locked position, in the unlocked position, the limiting block is received in the positioning groove, and the engaging rod does not extend through the mounting hole; and in the locked position, the resilient member is deformed, and the limiting block is engaged in the clipping groove to keep the engaging rod extending through the mounting hole to engage with a storage device.

### BACKGROUND

1. Technical Field

The present disclosure relates to mounting assembly, more particularly, to a mounting assembly for a storage device.

2. Description of Related Art

A typical personal computer includes data storage devices such as a hard disk drive (HDD), a floppy disk drive, and a compact disc-read only memory (CD-ROM) drive. Conventionally, the data storage devices are attached to a chassis of a computer enclosure using screws. A tool such as a screwdriver is used to fasten the screws, and to unfasten the screws when removing the data storage devices. Such operations are laborious and time-consuming. Furthermore, accidents may occur during operations (e.g., operator drops tools and screws). When this happens, other internal components of the computer are at risk of being damaged.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a mounting assembly, together with and a storage device, in accordance with an embodiment.

FIG. 2 is an exploded, isometric view of a mounting device of the mounting assembly.

FIG. 3 is an assembled view of FIG. 1.

FIG. 4 is a partial cross section, cutaway view of FIG. 3, and the mounting device is in an unlocked position.

FIG. 5 is similar to FIG. 4, and the mounting device is in a locked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

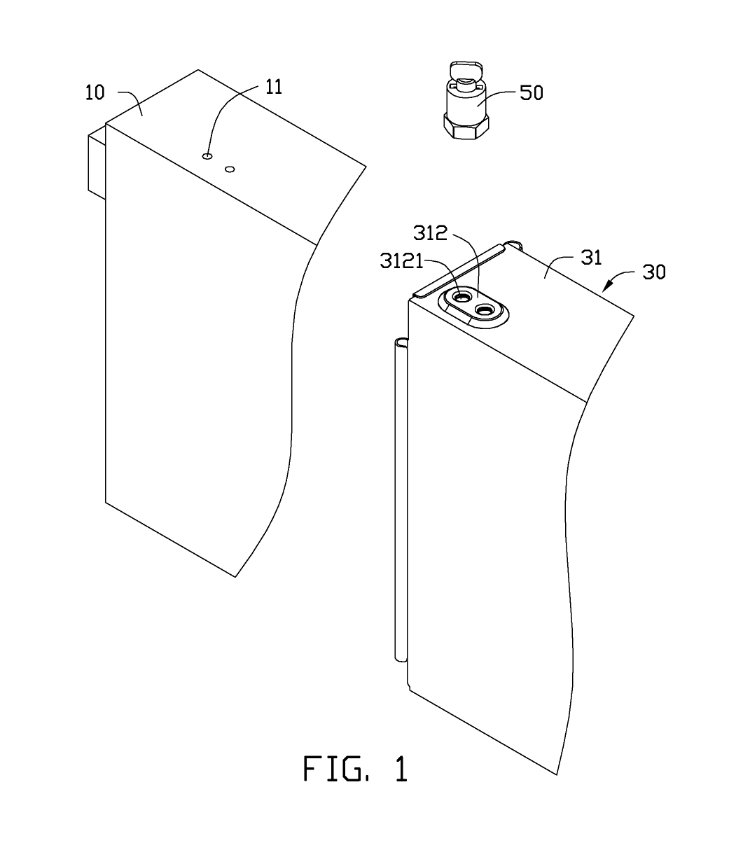

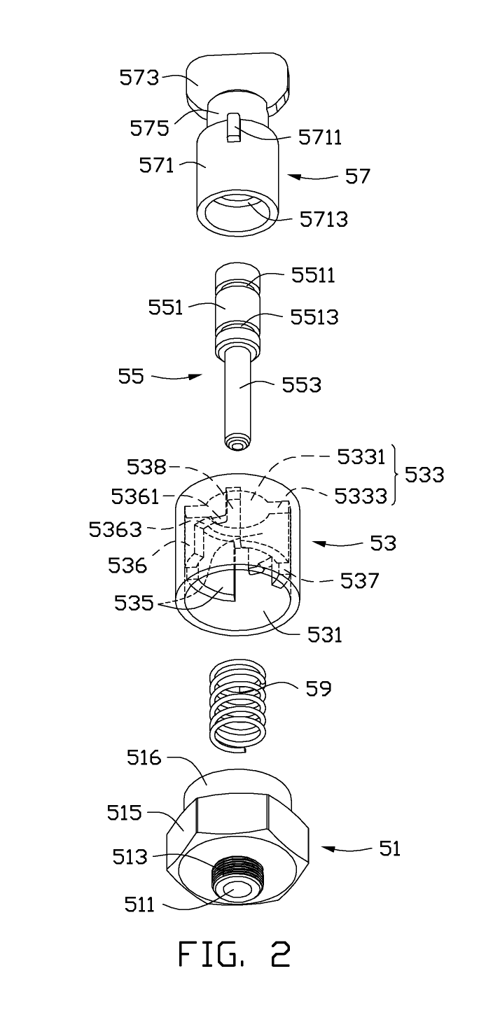

Referring to FIGS. 1 and 2, a mounting assembly in accordance with an embodiment includes an enclosure 30 and a mounting device 50 attached to the enclosure 30. In one embodiment, a storage device 10 is received in the enclosure 30 and defines two securing holes 11.

The enclosure 30 includes a top panel 31. A protrusion 312 protruding from the top panel 31 defines two mounting holes 3121. Each mounting hole 3121 corresponds to each securing hole 11 and has an inner screw thread. An opening (not shown) is defined in the enclosure 30 for the storage device 10 in or out of the enclosure 30.

Referring to FIG. 2, the mounting device 50 includes a mounting member 51, a engaging member 53 engaged with the mounting member 51, a engaging rod 55 moveably received in the mounting member 51 and the engaging member 53, a drive member 57 mounted to the mounting member 51, and a resilient member 59 surrounding the drive member 57.

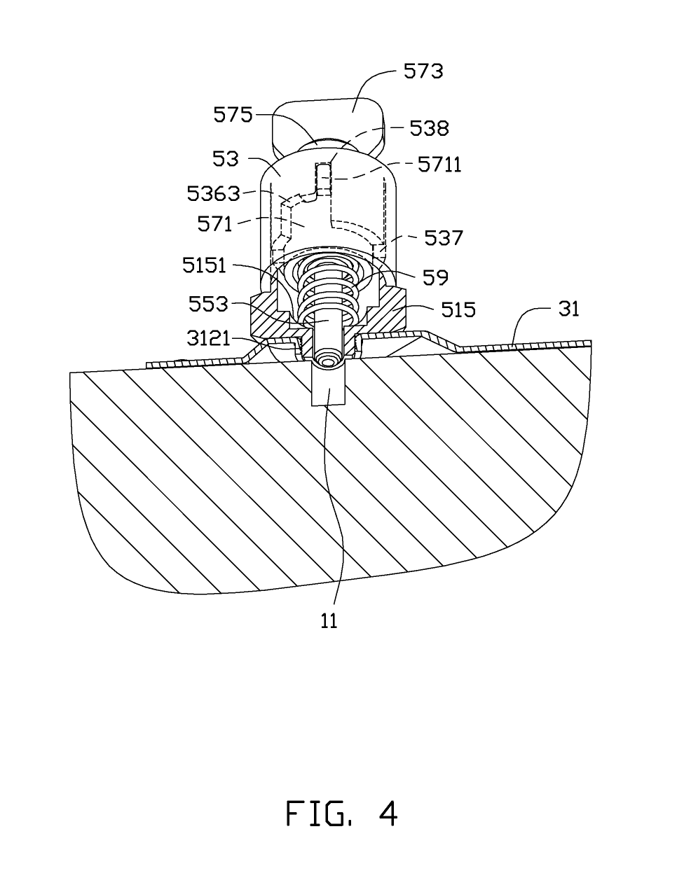

The mounting member 51 defines a through hole 511 and includes a mounting portion 513 with an outer screw thread, a base portion 515, and an extending portion 516. In one embodiment, the through hole 511 extends through the mounting portion 513, the base portion 515 and the extending portion 516. The base portion 515 is a hexagon, and a supporting portion 5151 (see FIG. 4) is located on the inner surface of the mounting member 51 and connected to the extending portion 546 and the base portion 515.

The engaging member 53 defines a receiving hole 531 and a pivot hole 533 communicating with the receiving hole 531. The pivot hole 533 includes a guiding portion 5331 and two extending holes 5333 connected to two opposite sides of the guiding portion 5331. In one embodiment, the guiding portion 5331 is circular, and the two extending holes 5333 are arranged at an extending line of a diameter of the guiding portion 5331. Two first positioning blocks 535 and two second positioning blocks 536 are located on the inner surface of the engaging member 53. Each second positioning block 536 is located between the two first positioning blocks 535. A sliding groove 537 and a positioning groove 538 are defined between each first positioning block 535 and each second positioning block 536. The sliding groove 537 and the positioning groove 538 are located on two sides of each first positioning block 535. In one embodiment, each sliding groove 537 communicates with each extending hole 5333.

A wedge 5361, adjacent to the positioning groove 538, is located on the second positioning block 536. A clipping groove 5363 is defined in the second positioning block 536. The clipping groove 5363 is adjacent to the wedge 5361. In one embodiment, the clipping groove 5363 is under the positioning groove 538, and the edge of the wedge 5361 is arcuate.

The engaging rod 55 includes a head 551 and a post 553 connected to the head 551. Two concave grooves 5511, 5513 are defined in the outer surface of the head 551. In one embodiment, a diameter of the head 551 is larger than that of the post 553.

The drive member 57 includes a case 571, a handle 573 and a connecting portion 575 connecting the case 571 and the handle 573. Two limiting blocks 5711, adjacent to the connecting portion 575, protrude from the outer surface of the case 571, and two sidesteps 5713 are defined in the inner surface of the case 571. The sidesteps 5713 correspond to the concave grooves 5511, 5513. In one embodiment, a length of the connecting portion 575 is larger than that of the first positioning block 535.

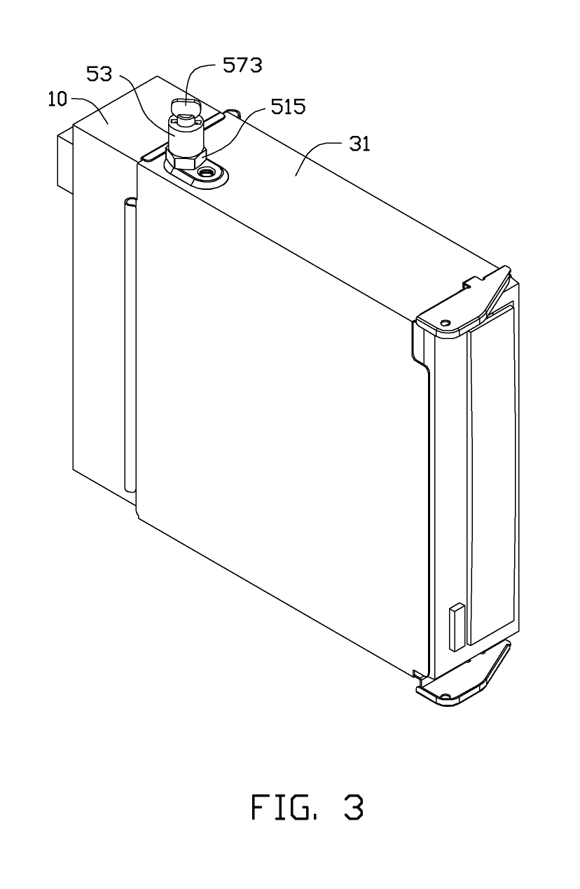

Referring to FIGS. 3-5, in assembly, the mounting portion 513 is engaged in one of the two mounting holes 3121. The extending portion 516 is received in the receiving hole 531, and a gap is defined between the extending portion 516 and the first and second positioning blocks 535, 536. The resilient member 59 surrounds the post 553. The head 551 is received in the case 571, and the concave grooves 551 are engaged with the sidesteps 5713, to secure the head 551 to the case 571.

The drive member 57, with the engaging rod 55 and the resilient member 59, is moved downward to be received in the engaging member 53. The limiting blocks 5711 are received in the extending holes 533, respectively, and the connecting portion 575 is exposed out of the engaging member 53. The resilient member 59 abuts the supporting portion 5151. The drive member 57 is further moved downward, and the connecting portion 575 is received in the receiving hole 531. The two limiting blocks 5711 extend through the corresponding extending holes 5333 and slide in the two sliding grooves 537, respectively. The resilient member 59 is deformed, until the limiting blocks 5711 are disengaged from the sliding grooves 537. The handle 573 is operated to rotate the drive member 57 clockwise, so that the limiting blocks 5711 move towards the positioning groove 538 relative to the bottom of the first positioning blocks 535. When the limiting blocks 5711 pass through the first positioning blocks 535 and reach the bottom of the positioning grooves 538, the resilient member 59 is then released to move the drive member 57 and the post 553 upward. The limiting blocks 5711 are slid in the positioning grooves 538, until clipped in the top end of the positioning grooves 538 (see FIG. 4).

The drive member 57 is rotatable relative to the engaging member 53 between an unlocked position and a locked position. In the unlocked position, the limiting blocks 5711 are clipped in the positioning grooves 538, the connecting portion 575 is exposed out of the engaging member 53, the resilient member 59 is in an original state, and the post 553 is received in the through hole 511. In the locked position, the limiting blocks 5711 are clipped in the clipping grooves 5363, the connecting portion 575 is received in the receiving hole 531, the resilient member 59 is deformed, and the post 553 is exposed out of the through hole 511.

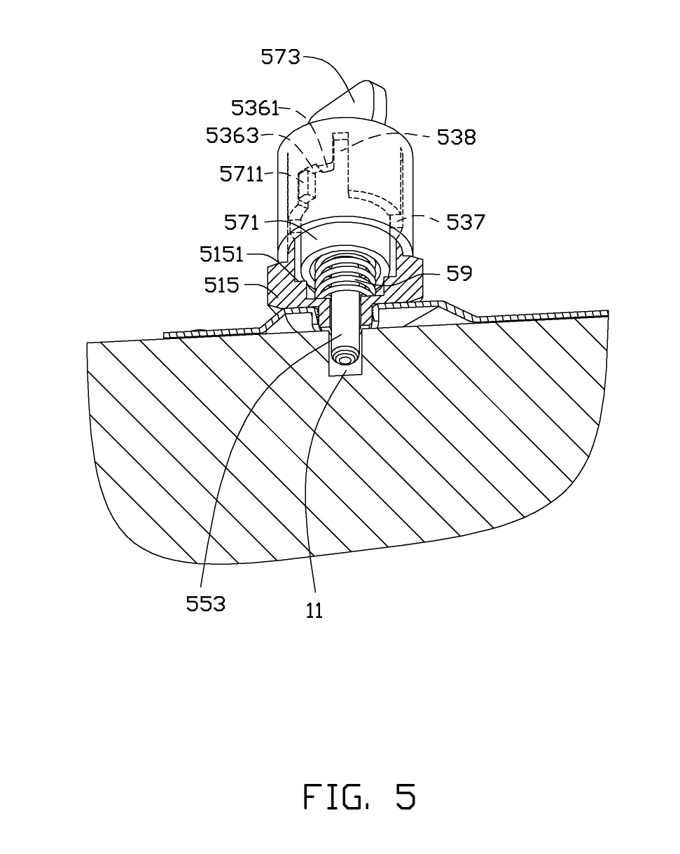

Referring FIGS. 4-5, in assembly of the storage device 10, the storage device 10 is received in the enclosure 30. One of the two securing holes 11 is aligned with one of the two mounting holes 3121. The drive member 57 is located in the unlocked position, and the post 553 is received in the through hole 511 and away from the securing hole 11. The handle 573 is operated to move the drive member 57 downward. The limiting blocks 5711 are slid downward in the positioning grooves 538, the resilient member 59 is deformed, and the post 553 is exposed out of the through hole 511 and engaged in the securing hole 11. When the limiting blocks 5711 are located under the wedges 5363, the handle 553 is operated clockwise. The limiting blocks 5711 are thus moved towards the clipping grooves 5363 relative to the wedge 5361, until the limiting blocks 5711 are engaged in the clipping grooves 5363. Therefore, the drive member 57 is located in the locked position, and the post 553 is engaged in the securing hole 11 to engage the storage device 10 with the enclosure 30.

In disassembly of the storage device 10, the handle 573 is moved downward, to disengage the limiting blocks 5711 from the clipping grooves 5353. The handle 573 is moved counterclockwise, so that the limiting blocks 5711 are moved to the bottom end of the positioning groove 538. The resilient member 59 is released to move the drive member 57 and the engaging rod 55 upward, until the limiting blocks 5711 are located at the top end of the positioning grooves 538. Therefore, the post 553 can be disengaged from the securing hole 11, and the storage device 10 can be removed from the enclosure 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting assembly comprising:
an enclosure defining a mounting hole;
an engaging member connected to the enclosure;
a drive member moveably connected to the engaging member, and comprising a limiting block;
an engaging rod attached to the drive member, and defining a positioning groove and a clipping groove therein;
a resilient member surrounding the engaging rod;
wherein the drive member is moveable relative to the engaging member between an unlocked position and a locked position, in the unlocked position, the limiting block is received in the positioning groove, and the engaging rod does not extend through the mounting hole; and in the locked position, the resilient member is deformed, and the limiting block is engaged in the clipping groove to keep the engaging rod extending through the mounting hole to engage with a storage device.

2. The mounting assembly of claim 1, wherein the drive member rotates relative to the engaging member to disengage the limiting block from the clipping groove.

3. The mounting assembly of claim 1, wherein the engaging member comprises a first positioning block and a second positioning block, on an inner surface of the engaging member, a sliding groove is defined between the first position block and the second positioning block, the sliding groove communicates with the clipping groove and the positioning groove, and the limiting block is slidably received in the sliding groove for disengaging the drive member from the engaging member.

4. The mounting assembly of claim 3, wherein the engaging member comprises a pivot hole, the pivot hole comprises a guiding portion and an extending hole connected to the guiding portion, the guiding portion receives the drive member, the extending hole communicates with the sliding groove, and the limiting block is slidable through the extending hole via the sliding groove.

5. The mounting assembly of claim 3, wherein the second positioning block comprises a wedge located between the positioning groove and the clipping groove, and the wedge prevents the drive member from being rotated from the unlocked position to the locked position.

6. The mounting assembly of claim 3, wherein the engaging member comprises two first positioning blocks and two second positioning blocks, each first positioning block is located between the two second positioning block, and the positioning groove and the sliding groove are located on two sides of each first positioning block.

7. The mounting assembly of claim 1, wherein the drive member comprises a connecting case, the limiting block is located on an outer surface of the case, the engaging rod comprises a head and a post connected to the head, the head is received in the case, and the resilient member is attached to the post.

8. The mounting assembly of claim 7, further comprising a mounting member, the resilient member abuts the mounting member, the mounting member defines a through hole communicating with the mounting hole, when the drive member is located in the unlocked position, the post is received in the through hole, and when the drive member is located in the locked position, the post is exposed out of the through hole.

9. The mounting assembly of claim 7, wherein the drive member further comprises a connecting portion connected to the case, the connecting portion is exposed out of the engaging member when the drive member is located on the unlocked position, and the connecting portion is received in the engaging member when the drive member is located on the locked position.

10. The mounting assembly of claim 9, wherein the drive member further comprises a handle, and the handle is connected to the connecting portion.

11. A mounting assembly comprising:
an enclosure defining a mounting hole;
a mounting device comprising an engaging member, a drive member moveably received in the engaging member, an engaging rod attached to the drive member, and a mounting member attached to the enclosure; a positioning groove and a clipping groove defined in the engaging member; the drive member comprising a limiting block slidably received in the positioning groove; a resilient member surrounding the engaging rod and located between the drive member and the mounting member; and the mounting member defines a through hole communicating with the mounting hole;
wherein the drive member is moveable relative to the engaging member to disengage the limiting block from the positioning groove, the limiting block is engaged in the clipping hole to deform the resilient member, and the engaging rod is exposed out of the engaging member to extend through the through hole and the mounting hole, and engage in a securing hole of a storage device.

12. The mounting assembly of claim 11, wherein the engaging member comprises a first positioning block and a second positioning block, on an inner surface of the engaging member, a sliding groove is defined between the first position block and the second positioning block, the sliding groove communicates with the clipping groove and the positioning groove, and the limiting block is slidably received in the sliding groove for disengaging the drive member from the engaging member.

13. The mounting assembly of claim 12, wherein the engaging member comprises a pivot hole, the pivot hole comprises a guiding portion and a extending hole connected to the guiding portion, the guiding portion receives the drive member, the extending hole communicates with the sliding groove, and the limiting block is slid in the sliding groove through the extending hole via the sliding groove.

14. The mounting assembly of claim 12, wherein the second positioning block comprises a wedge located between the positioning groove and the clipping groove, and the wedge prevents the drive member from being rotated when the limiting block is engaged in the clipping groove.

15. The mounting assembly of claim 12, wherein the engaging member comprises two first positioning blocks and two second positioning blocks, each first positioning block is located between the two second positioning block, and the positioning groove and the sliding groove are located on two sides of each first positioning block.

16. The mounting assembly of claim 11, wherein the drive member comprises a connecting case, the limiting block is located on an outer surface of the case, the engaging rod comprises a head and a post connected to the head, the head is received in the case, and the resilient member is attached to the post.

17. The mounting assembly of claim 16, wherein when the limiting block is engaged in the positioning groove, the post is received in the through hole, and when the limiting block is engaged in the clipping groove, the post is exposed out of the through hole.

18. The mounting assembly of claim 16, wherein the drive member further comprises a connecting portion connected to the case, the connecting portion is exposed out of the engaging member when the limiting block is engaged in the positioning groove, and the connecting portion is received in the engaging member when the limiting block is engaged in the clipping groove,.

19. The mounting assembly of claim 18, wherein the drive member further comprises a handle, and the handle is connected to the connecting portion.
